(19) United States
(12) Patent Application Publication
(10) Pub. No.: US 2012/0299016 A1
(43) Pub. Date: Nov. 29, 2012

(54) ORGANIC LAYER DEPOSITION APPARATUS AND METHOD OF MANUFACTURING ORGANIC LIGHT EMITTING DISPLAY DEVICE USING THE ORGANIC LAYER DEPOSITION APPARATUS

(76) Inventor: Myong-Hwan Choi, Yongin-city (KR)

(21) Appl. No.: 13/469,029

(22) Filed: May 10, 2012

(30) Foreign Application Priority Data
May 25, 2011 (KR) 10-2011-0049795

(51) Int. Cl. H01L 33/02; B05B 1/14; B05B 1/34

(52) U.S. Cl. 257/79; 438/46; 118/304; 257/E33.013

(57) ABSTRACT

An organic layer deposition apparatus capable of protecting or preventing a patterning slit sheet from sagging, and a method of manufacturing an organic light-emitting display device by using the organic layer deposition apparatus.

### CROSS-REFERENCE TO RELATED PATENT APPLICATION

This application claims priority to and the benefit of Korean Patent Application No. 10-2011-0049795, filed on May 25, 2011, in the Korean Intellectual Property Office, the disclosure of which is incorporated herein in its entirety by reference.

### BACKGROUND

1. Field

Aspects of embodiments according to the present invention relate to an organic layer deposition apparatus and a method of manufacturing an organic light-emitting display device by using the same.

2. Description of the Related Art

Organic light-emitting display devices have a larger viewing angle, better contrast characteristics, and a faster response rate than other display devices, and thus have drawn attention as a next-generation display device.

An organic light-emitting display device includes intermediate layers, including an emission layer disposed between a first electrode and a second electrode that are arranged opposite to (i.e., arranged to face) each other. The electrodes and the intermediate layers may be formed via various suitable methods, one of which is a deposition method. When an organic light-emitting display device is manufactured by using the deposition method, a fine metal mask (FMM) having the same pattern as, for example, an organic layer to be formed, is disposed to closely contact a substrate, on which the organic layer, for example, is to be formed; and an organic layer material, for example, is deposited over the FMM in order to form the organic layer having the desired pattern.

### SUMMARY

In order to address the drawback of a conventional deposition method using a fine metal mask (FMM), aspects of embodiments according to the present invention are directed toward an organic layer deposition apparatus that is suitable for producing large-sized display devices on a mass scale and that is capable of protecting or preventing a patterning slit sheet from sagging, and a method of manufacturing an organic light-emitting display device by using the organic layer deposition apparatus.

According to an embodiment of the present invention, there is provided an organic layer deposition apparatus for forming an organic layer on a substrate, the apparatus including a deposition source configured to discharge a deposition material; a deposition source nozzle unit disposed at a side of the deposition source and including a plurality of deposition source nozzles arranged in a first direction; and a patterning slit sheet disposed to face (opposite to) the deposition source nozzle unit and including a split sheet having a plurality of patterning slits arranged in a second direction perpendicular to the first direction, wherein the substrate or the organic layer deposition apparatus is moved relative to the other in the first direction to perform a deposition.

The patterning slit sheet may comprise a plurality of the split sheets, and a support may be disposed between the split sheets.

The split sheets may be arranged in the first direction.

A length of a side of each of the split sheets that is parallel to the second direction may be greater than a length of a side of each of the split sheets that is parallel to the first direction.

The split sheets may be arranged in the second direction.

A length of a side of each of the split sheets that is parallel to the second direction may be smaller than a length of a side of each of the split sheets that is parallel to the first direction.

The patterning slit sheet may further comprise support sheets, and the support sheets may be disposed on both opposite sides of the split sheet, respectively.

The patterning slit sheet may further comprise supports that are disposed between the support sheets and the split sheet to support the support sheets and the split sheet.

The deposition source, the deposition source nozzle unit, and the patterning slit sheet may be integrally formed as one body.

The deposition source and the deposition source nozzle unit, and the patterning slit sheet may be integrally connected as one body by a connection member for guiding movement of the deposition material.

The connection member may seal a space between the deposition source nozzle unit disposed at the side of the deposition source, and the patterning slit sheet.

The plurality of deposition source nozzles may be tilted at an angle.

The plurality of deposition source nozzles may include deposition source nozzles arranged in two rows formed in the first direction, and the deposition source nozzles in the two rows may be tilted to face each other.

The plurality of deposition source nozzles may comprise deposition source nozzles arranged in two rows formed in the first direction, the deposition source nozzles of one of the two rows located at a first side of the patterning slit sheet may be arranged to face a second side of the patterning slit sheet, and the deposition source nozzles of the other one of the two rows located at the second side of the patterning slit sheet may be arranged to face the first side of the patterning slit sheet.

According to another embodiment of the present invention, there is provided an organic layer deposition apparatus for forming an organic layer on a substrate, the apparatus including a deposition source configured to discharge a deposition material; a deposition source nozzle unit disposed at a side of the deposition source and including a plurality of deposition source nozzles arranged in a first direction; a patterning slit sheet disposed opposite to the deposition source nozzle unit and having a plurality of patterning slits arranged in the first direction; and a barrier plate assembly that comprises a plurality of barrier plates that are disposed between the deposition source nozzle unit and the patterning slit sheet in the first direction and partition a space between the deposition source nozzle unit and the patterning slit sheet into a plurality of sub-deposition spaces, wherein the organic layer deposition apparatus and the substrate are separated from each other, and the organic layer deposition apparatus or the substrate is moved relative to the other.

The plurality of barrier plates may extend in a second direction perpendicular to the first direction.

The barrier plate assembly may comprise a first barrier plate assembly including a plurality of first barrier plates, and a second barrier plate assembly including a plurality of second barrier plates.

Each of the first barrier plates and each of the second barrier plates may extend in a second direction perpendicular to the first direction.

The first barrier plates may be arranged to respectively correspond to the second barrier plates.

The deposition source and the barrier plate assembly may be separated from each other.

The barrier plate assembly and the patterning slit sheet may be separated from each other.

The patterning slit sheet may comprise a plurality of the split sheets, and a support may be disposed between the split sheets.

The split sheets may be arranged in the first direction.

A length of a side of each of the split sheets that is parallel to the second direction may be greater than a length of a side of each of the split sheets that is parallel to the first direction.

The split sheets may be arranged in the second direction.

A length of a side of each of the split sheets that is parallel to the second direction may be smaller than a length of a side of each of the split sheets that is parallel to the first direction.

The patterning slit sheet may further comprise support sheets, and the support sheets may be disposed on both opposite sides of the split sheet, respectively.

The patterning slit sheet may further comprise supports that are disposed between the support sheets and the split sheet to support the support sheets and the split sheet.

According to another embodiment of the present invention, there is provided a method of manufacturing an organic light-emitting display device, the method including separating an organic layer deposition apparatus from a substrate on which deposition is to occur, by a distance, wherein the organic layer deposition apparatus comprises: a deposition source that discharges a deposition material; a deposition source nozzle unit disposed at a side of the deposition source and including a plurality of deposition source nozzles arranged in a first direction; and a patterning slit sheet disposed opposite to the deposition source nozzle unit and including a split sheet comprising a plurality of patterning slits; and the method further includes depositing the deposition material discharged from the organic layer deposition apparatus onto the substrate while the organic layer deposition apparatus or the substrate is moved relative to the other.

The patterning slit sheet may further comprise support sheets, and the support sheets may be disposed on both opposite sides of the split sheet, respectively.

The patterning slit sheet may further comprise supports that are disposed between the support sheets and the split sheet to support the support sheets and the split sheet.

The deposition source nozzle unit may comprise a plurality of deposition source nozzles arranged in a first direction, and the patterning slit sheet may comprise a plurality of patterning slits arranged in a second direction perpendicular to the first direction.

The deposition source nozzle unit may comprise a plurality of deposition source nozzles arranged in a first direction, the patterning slit sheet may include a plurality of patterning slits arranged in the first direction. The organic layer deposition apparatus may further include a barrier plate assembly including a plurality of barrier plates that are disposed between the deposition source nozzle unit and the patterning slit sheet in the first direction, and partition a space between the deposition source nozzle unit and the patterning slit sheet into a plurality of sub-deposition spaces.

As described above, according to aspects of embodiments of the present invention, an organic light-emitting display device may be easily manufactured and may be simply applied to the manufacture of large-sized display devices on a mass scale, manufacturing yield and deposition efficiency may be improved, and a patterning slit sheet may be prevented from sagging.

### BRIEF DESCRIPTION OF THE DRAWINGS

The above and other features and aspects of the present invention will become more apparent by describing in detail exemplary embodiments thereof with reference to the attached drawings in which:

FIG. 1 is a schematic view of an organic layer deposition system including an organic layer deposition apparatus according to an embodiment of the present invention;

FIG. 2 illustrates a modified example of the organic layer deposition system of FIG. 1;

FIG. 3 is a view of an example of an electrostatic chuck;

FIG. 4 is a schematic perspective view of an organic layer deposition apparatus according to an embodiment of the present invention;

FIG. 5 is a schematic side view of the organic layer deposition apparatus of FIG. 4, according to an embodiment of the present invention;

FIG. 6 is a schematic sectional view in an XZ plane of the organic layer deposition apparatus of FIG. 4, according to an embodiment of the present invention;

FIG. 7 is a plan view schematically illustrating a patterning slit sheet of the organic layer deposition apparatus of FIG. 4;

FIG. 8 is a plan view schematically illustrating a patterning slit sheet according to another embodiment of the present invention;

FIG. 9 is a plan view schematically illustrating a patterning slit sheet according to another embodiment of the present invention;

FIG. 10 is a schematic perspective view of an organic layer deposition apparatus according to another embodiment of the present invention;

FIG. 11 is a schematic perspective view of an organic layer deposition apparatus according to another embodiment of the present invention;

FIG. 12 is a schematic perspective cutaway view of an organic layer deposition apparatus according to another embodiment of the present invention;

FIG. 13 is a schematic side cross-sectional view of the organic layer deposition apparatus of FIG. 12, according to an embodiment of the present invention;

FIG. 14 is a schematic plan sectional view in an XZ plane of the organic layer deposition apparatus of FIG. 12, according to an embodiment of the present invention;

FIG. 15 is a schematic perspective cutaway view of an organic layer deposition apparatus according to another embodiment of the present invention; and

FIG. 16 is a cross-sectional view of an organic light-emitting display device manufactured by using an organic layer deposition apparatus, according to an embodiment of the present invention.

### DETAILED DESCRIPTION

One or more aspects of embodiments according to the present invention will now be described more fully with reference to the accompanying drawings in which exemplary embodiments of the invention are shown. In the drawings, the thicknesses of layers and regions may be exaggerated for clarity. Like reference numerals in the drawings denote like elements, and thus their description will be omitted.

A deposition method using a conventional FMM is generally not suitable for manufacturing larger devices using a mother glass having a fifth-generation (5G) (1100 mm×1300 mm) or greater. In other words, when such a large mask is used, the mask may bend due to its own weight, thereby distorting a pattern. This is not conducive for the recent trend towards high-definition patterns.

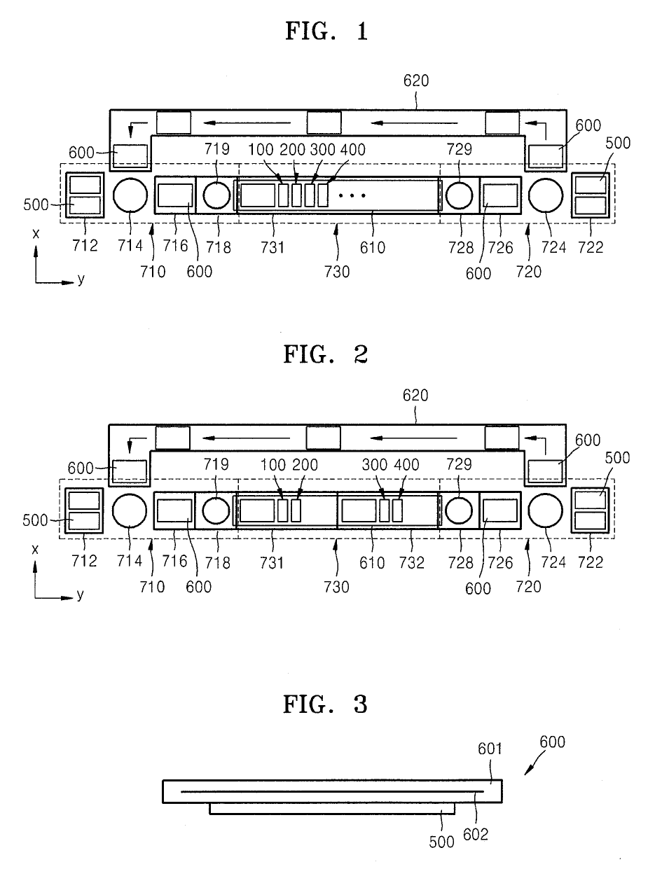

FIG. 1 is a schematic perspective view of an organic layer deposition system including an organic layer deposition apparatus according to an embodiment of the present invention. FIG. 2 illustrates a modified example of the organic layer deposition system of FIG. 1. FIG. 3 is a view of an example of an electrostatic chuck 600.

Referring to FIG. 1, the organic layer deposition system according to the current embodiment includes a loading unit 710, a deposition unit 730, an unloading unit 720, a first conveyer unit 610, and a second conveyer unit 620.

The loading unit 710 may include a first rack 712, a transport robot 714, a transport chamber 716, and a first inversion chamber 718.

A plurality of substrates 500 onto which a deposition material is not applied are stacked up on the first rack 712. The transport robot 714 picks up one of the substrates 500 from the first rack 712, disposes it on the electrostatic chuck 600 transferred by the second conveyor unit 620, and moves the electrostatic chuck 600 on which the substrate 500 is disposed, into the transport chamber 716.

The first inversion chamber 718 is disposed adjacent to the transport chamber 716. The first inversion chamber 718 includes a first inversion robot 719 that inverts the electrostatic chuck 600 and then loads it onto the first conveyer unit 610 of the deposition unit 730.

Referring to FIG. 3, the electrostatic chuck 600 may include an electrode 602 embedded in a main body 601 of the electrostatic chuck 600. Here, the main body 601 is formed of ceramic, and the electrode 602 is supplied with power. The electrostatic chuck 600 may fix the substrate 500 on a surface of the main body 601 as a high voltage is applied to the electrode 602.

Referring back to FIG. 1, the transport robot 714 places one of the substrates 500 on an upper surface of the electrostatic chuck 600, and the electrostatic chuck 600 on which the substrate 500 is disposed is loaded into the transport chamber 716. The first inversion robot 719 inverts the electrostatic chuck 600 so that the substrate 500 is turned upside down in the deposition unit 730.

The unloading unit 720 is constituted to operate in an opposite manner to the loading unit 710 described above. Specifically, a second inversion robot 729 in a second inversion chamber 728 inverts the electrostatic chuck 600, which has passed through the deposition unit 730 while the substrate 500 is disposed on the electrostatic chuck 600, and then moves the electrostatic chuck 600 on which the substrate 500 is disposed into an ejection chamber 726. Then, an ejection robot 724 removes the electrostatic chuck 600 on which the substrate 500 is disposed from the ejection chamber 726, separates the substrate 500 from the electrostatic chuck 600, and then loads the substrate 500 onto a second rack 722. The electrostatic chuck 600 separated from the substrate 500 is returned back into the loading unit 710 via the second conveyer unit 620.

However, the present invention is not limited to the above description. For example, when disposing the substrate 500 on the electrostatic chuck 600, the substrate 500 may be fixed onto a lower surface of the electrostatic chuck 600 and then moved into the deposition unit 730. In this case, for example, the first inversion chamber 718 and the first inversion robot 719, and the second inversion chamber 728 and the second inversion robot 729 are not used.

The deposition unit 730 may include at least one deposition chamber. As illustrated in FIG. 1, the deposition unit 730 may include a first chamber 731. In the embodiment illustrated in FIG. 1, first to fourth organic layer deposition apparatuses 100, 200, 300, and 400 may be disposed in the first chamber 731. Although FIG. 1 illustrates that a total of four organic layer deposition apparatuses, i.e., the first to fourth organic layer deposition assemblies 100 to 400, are installed in the first chamber 731, the total number of organic layer deposition apparatuses that may be installed in the first chamber 731 may vary according to the deposition material and deposition conditions. The first chamber 731 is maintained in a vacuum state during a deposition process.

In the organic layer deposition apparatus illustrated in FIG. 2, the deposition unit 730 may include the first chamber 731 and a second chamber 732 that are connected to each other. In the embodiment illustrated in FIG. 2, first and second organic layer deposition apparatuses 100 and 200 may be disposed in the first chamber 731, and the third and fourth organic layer deposition apparatuses 300 and 400 may be disposed in the second chamber 732. In other embodiments, the organic layer deposition system may include more than two chambers.

In the embodiment illustrated in FIG. 1, the electrostatic chuck 600 on which the substrate 500 is disposed may be moved at least to the deposition unit 730 or may be moved sequentially to the loading unit 710, the deposition unit 730, and the unloading unit 720, by the first conveyor unit 610. The electrostatic chuck 600 that is separated from the substrate 500 in the unloading unit 720 is moved back to the loading unit 710 by the second conveyor unit 620.

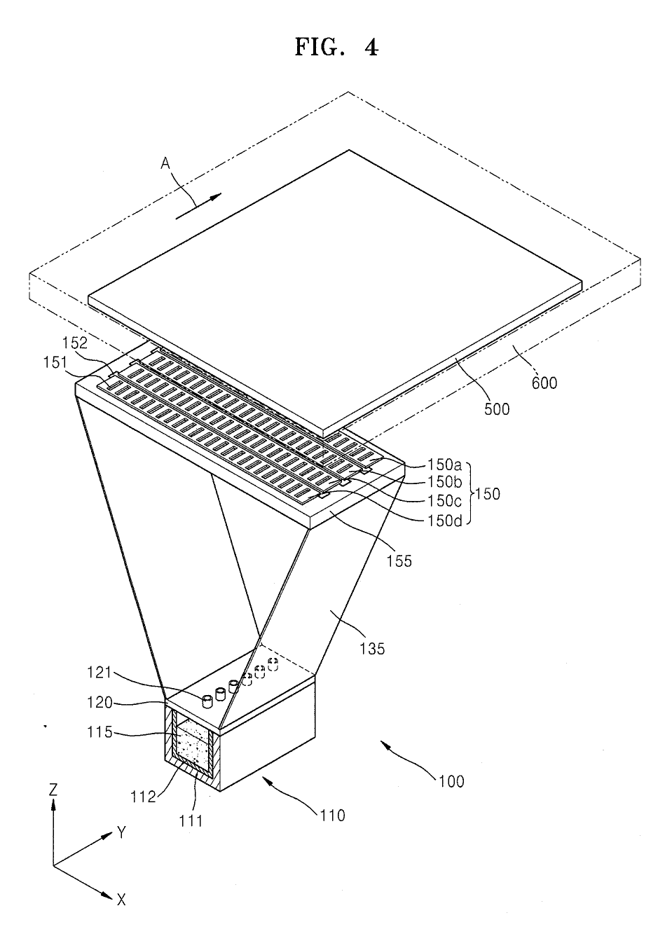

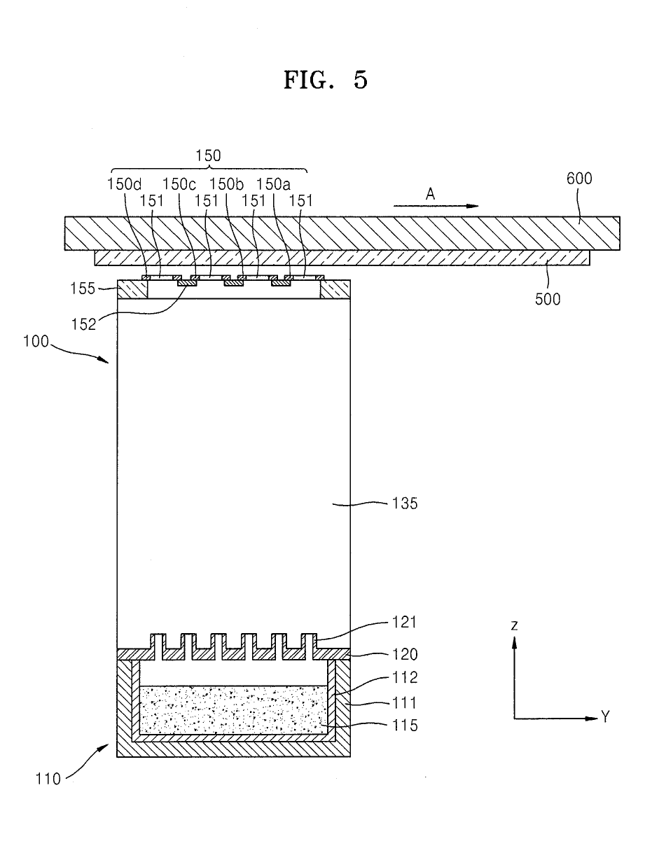

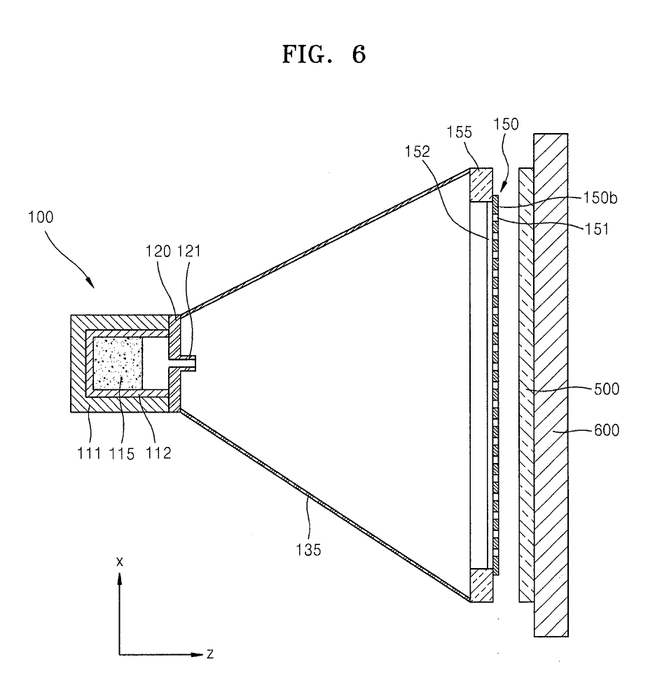

FIG. 4 is a schematic perspective view of an organic layer deposition apparatus 100 according to an embodiment of the present invention, FIG. 5 is a schematic sectional view of the organic layer deposition apparatus 100 illustrated in FIG. 4, and FIG. 6 is a schematic sectional view in an XZ plane of the organic layer deposition apparatus 100 illustrated in FIG. 4.

Referring to FIGS. 4 through 6, the organic layer deposition apparatus 100 according to the current embodiment of the present invention includes a deposition source 110, a deposition source nozzle unit 120, and a patterning slit sheet 150.

For example, in order to deposit a deposition material 115 that is emitted from the deposition source 110 and is discharged through the deposition source nozzle unit 120 and the patterning slit sheet 150, onto a substrate 500 in a desired pattern, the first chamber 731 should be maintained in a high-vacuum state as in a deposition method using a fine metal mask (FMM). In addition, the temperature of the patterning slit sheet 150 should be sufficiently lower than the temperature of the deposition source 110. In this regard, the temperature of the patterning slit sheet 150 may be about 100° C. or less. The temperature of the patterning slit sheet 150 should be sufficiently low so as to reduce thermal expansion of the patterning slit sheet 150.

The substrate 500, which constitutes a deposition target on which the deposition material 115 is to be deposited, is disposed in the first chamber 731. The substrate 500 may be a substrate for flat panel displays. A large substrate, such as a mother glass, for manufacturing a plurality of flat panel displays, may be used as the substrate 500. Other suitable substrates may also be employed.

In the current embodiment of the present invention, deposition may be performed while the substrate 500 or the organic layer deposition apparatus 100 is moved relative to the other.

In particular, in a typical FMM deposition method, the size of the FMM is generally equal to the size of a substrate. Thus, the size of the FMM is increased as the substrate becomes larger. However, it is neither straightforward to manufacture a large FMM nor to extend an FMM to be accurately aligned with a pattern.

In order to overcome this problem, in the organic layer deposition apparatus 100 according to the current embodiment of the present invention, deposition may be performed while the organic layer deposition apparatus 100 or the substrate 500 is moved relative to the other. In other words, deposition may be continuously performed while the substrate 500, which is disposed such as to face the organic layer deposition apparatus 100, is moved in a Y-axis direction. In other words, deposition may be performed in a scanning manner while the substrate 500 is moved in a direction of arrow A in FIG. 6 (first direction).

In the organic layer deposition apparatus 100 according to the current embodiment of the present invention, the patterning slit sheet 150 may be significantly smaller than an FMM used in a typical deposition method. In other words, in the organic layer deposition apparatus 100 according to the current embodiment of the present invention, deposition is continuously performed, i.e., in a scanning manner while the substrate 500 is moved in the Y-axis direction. Thus, lengths of the patterning slit sheet 150 in the X-axis and Y-axis directions may be less (e.g., significantly less) than the lengths of the substrate 500 in the X-axis and Y-axis directions. As described above, since the patterning slit sheet 150 may be formed to be smaller (e.g., significantly smaller) than an FMM used in a conventional deposition method, it is relatively easy to manufacture the patterning slit sheet 150 used in embodiments of the present invention. In other words, using the patterning slit sheet 150, which is smaller than an FMM used in a conventional deposition method, is more convenient in all processes, including etching and other subsequent processes, such as precise extension, welding, moving, and cleaning processes, compared to the conventional deposition method using the larger FMM. This is more advantageous for a relatively large display device.

The deposition source 110 that contains and heats the deposition material 115 is disposed at an opposite side of the chamber to a side at which the substrate 500 is disposed. While the deposition material 115 contained in the deposition source 110 is vaporized, the deposition material 115 is deposited on the substrate 500.

For example, the deposition source 110 includes a crucible 112 that is filled with the deposition material 115 and a cooling block 111 that heats the crucible 112, to vaporize the deposition material 115 which is contained in the crucible 112, towards a side of the crucible 111, and in particular, towards the deposition source nozzle unit 120. The cooling block 111 reduces or prevents radiation of heat from the crucible 112 to the outside, e.g., into the first chamber 731. The cooling block 111 may include a heater that heats the crucible 111.

The deposition source nozzle unit 120 is disposed at a side of the deposition source 110, and in particular, at the side of the deposition source 110 facing the substrate 500. The deposition source nozzle unit 120 includes a plurality of deposition source nozzles 121 arranged at equal intervals in the Y-axis direction, i.e., a scanning direction of the substrate 500. The deposition material 115 that is vaporized in the deposition source 110, passes through the deposition source nozzle unit 120 toward the substrate 500 on which the deposition material 115 is to be deposited. As described above, the deposition source nozzle unit 120 includes the plurality of deposition source nozzles 121 arranged in the Y-axis direction, that is, the scanning direction of the substrate 500. Here, the size of a pattern formed of the deposition material discharged through the patterning slits 151 of the patterning slit sheet 150 is affected by the size of one of the deposition source nozzles 121 (since there is only one disposition nozzle 121 in the X-axis direction), and thus no shadow zone may be formed on the substrate 500. In addition, since the plurality of deposition source nozzles 121 are arranged in the scanning direction of the substrate 500, even if there is a difference in flux between the deposition source nozzles 121, the difference may be compensated for and deposition uniformity may be maintained constant.

The patterning slit sheet 150 and a frame 155 in which the patterning slit sheet 150 is bound, are disposed between the deposition source 110 and the substrate 500. The patterning slit sheet 150 includes a plurality of split sheets 150a, 150b, 150c, and 150d, each having a plurality of patterning slits 151 arranged in the X-axis direction. The deposition material 115 that is vaporized in the deposition source 110, passes through the deposition source nozzle unit 120 and the patterning slits 151 toward the substrate 500 on which the deposition material 115 is to be deposited. Supports 152 may be disposed between the split sheets 150a, 150b, 150c, and 150d. The frame 155 may be formed in a lattice shape, similar to a window frame. The split sheets 150a, 150b, 150c, and 150d may be bound inside the frame 155. The patterning slit sheet 150 will be described in more detail below.

In addition, the deposition source 110 and the deposition source nozzle unit 120 coupled to the deposition source 110 may be disposed to be separated from the patterning slit sheet 150 by a distance (e.g., a predetermined distance). Alternatively, the deposition source 110 and the deposition source nozzle unit 120 coupled to the deposition source 110 may be connected to the patterning slit sheet 150 by a connection member 135. That is, the deposition source 110, the deposition source nozzle unit 120, and the patterning slit sheet 150 may be integrally formed as one body by being connected to each other via the connection member 135. The connection member 135 guides the deposition material 115, which is discharged through the deposition source nozzles 121, to move straight, not to flow in the X-axis direction. In FIGS. 4, 5, and 6, the connection members 135 are formed on left and right sides of the deposition source 110, the deposition source nozzle unit 120, and the patterning slit sheet 150 to guide the deposition material 115 not to flow in the X-axis direction; however, aspects of the present invention are not limited thereto. That is, the connection member 135 may be formed as a sealed box to guide flow of the deposition material 115 both in the X-axis and Y-axis directions.

As described above, the organic layer deposition apparatus 100 according to the current embodiment of the present invention, performs deposition while being moved relative to the substrate 500. In order to move the organic layer deposition apparatus 100 relative to the substrate 500, the patterning slit sheet 150 is separated from the substrate 500 by a distance (e.g., a predetermined distance).

In particular, in a typical deposition method using an FMM, deposition is performed with the FMM in close contact with a substrate in order to reduce or prevent formation of a shadow zone on the substrate. However, when the FMM is used in close contact with the substrate, the contact may cause defects. In addition, in the conventional deposition method, the size of the mask is the same as the size of the substrate since the mask cannot be moved relative to the substrate. Thus, the size of the mask is increased as display devices become larger. However, it is not easy to manufacture such a large mask.

In order to overcome this problem, in the organic layer deposition apparatus 100 according to the current embodiment of the present invention, the patterning slit sheet 150 is disposed to be separated from the substrate 500 by a distance (e.g., a predetermined distance).

As described above, according to embodiments of the present invention, a mask is formed to be smaller than a substrate, and deposition is performed while the mask is moved relative to the substrate. Thus, the mask can be easily manufactured. In addition, defects caused due to the contact between a substrate and an FMM, which may occur in the conventional deposition method, may be reduced or prevented. Furthermore, since it is unnecessary to dispose the FMM in close contact with the substrate during a deposition process, the manufacturing time may be reduced.

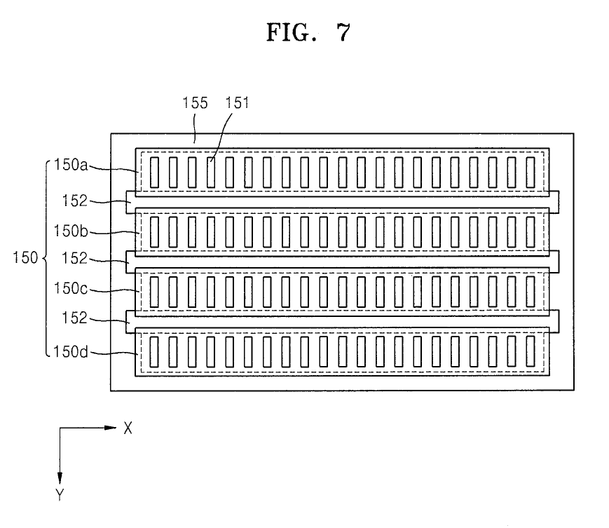

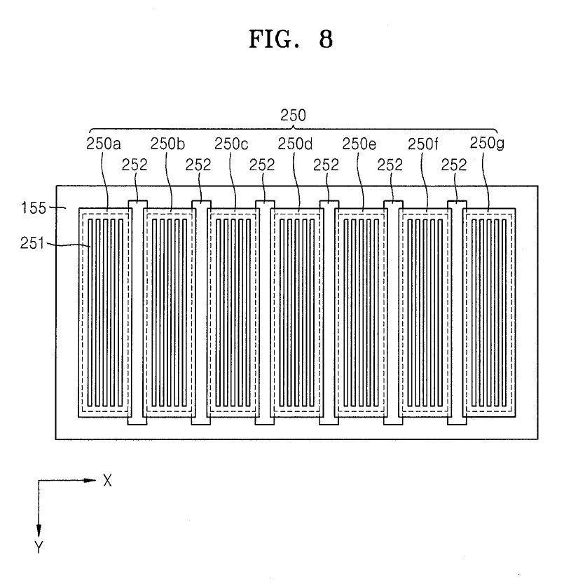

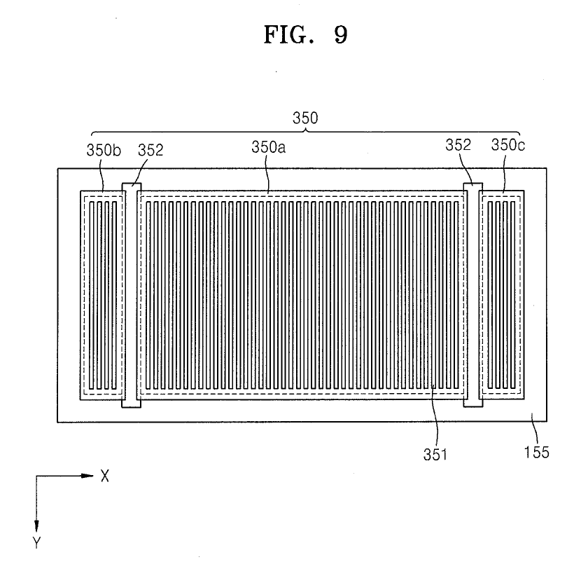

FIG. 7 is a plan view schematically illustrating the patterning slit sheet 150 of FIG. 4. Referring to FIG. 7, the patterning slit sheet 150 may include the split sheets 150a, 150b, 150c, and 150d and the supports 152.

Each of the split sheets 150a, 150b, 150c, and 150d may have the plurality of patterning slits 151, and the patterning slits 151 may be penetrated regions extending in a first direction (Y-axis direction) and may be arranged in a second direction (X-axis direction) perpendicular to the first direction. The split sheets 150a, 150b, 150c, and 150d may be arranged in the first direction (Y-axis direction). In this case, each of the split sheets 150a, 150b, 150c, and 150d may be formed so that the length of a side thereof parallel to the second direction is longer than that at a side thereof parallel to the first direction. Although the four split sheets 150a, 150b, 150c, and 150d are illustrated in FIG. 7, the present invention is not limited thereto. The patterning slit sheet 150 may include two or more split sheets.

Since the patterning slit sheet 150 includes the plurality of split sheets 150a, 150b, 150c, and 150d as described above, the tensile force of the patterning slit sheet 150 may be reduced, and thus deformation of the patterning slits 151 may be reduced. When some of the split sheets 150a, 150b, 150c, and 150d are damaged, only the damaged split sheets may be replaced, leading to easy maintenance and cost reduction.

The supports 152 may be disposed between the split sheets 150a, 150b, 150c, and 150d. The supports 152 may protect or prevent the split sheets 150a, 150b, 150c, and 150d from sagging.

FIG. 8 is a plan view schematically illustrating a patterning slit sheet 250 according to another embodiment of the present invention. Referring to FIG. 8, the patterning slit sheet 250 may include split sheets 250a, 250b, 250c, 250d, 250e, 250f, and 250g and supports 252.

Each of the split sheets 250a, 250b, 250c, 250d, 250e, 250f, and 250g may include a plurality of patterning slits 251, and the patterning slits 251 may be penetrated regions extending in a first direction (Y-axis direction) and may be arranged in a second direction (X-axis direction) perpendicular to the first direction. The split sheets 250a, 250b, 250c, 250d, 250e, 250f, and 250g may be arranged in the second direction (X-axis direction). In this case, each of the split sheets 250a, 250b, 250c, 250d, 250e, 250f, and 250g may be formed so that the length of a side thereof parallel to the second direction is smaller than that of a side thereof parallel to the first direction. Although the 7 split sheets 250a, 250b, 250c, 250d, 250e, 250f, and 250g are illustrated in FIG. 8, the present invention is not limited thereto. The patterning slit sheet 250 may include two or more split sheets.

Since the patterning slit sheet 250 includes the plurality of split sheets 250a, 250b, 250c, 250d, 250e, 250f, and 250g as described above, the tensile force of the patterning slit sheet 250 may be reduced, and thus deformation of the patterning slits 251 may be reduced. When some of the split sheets 250a, 250b, 250c, 250d, 250e, 250f, and 250g are damaged, only the damaged split sheets may be replaced, leading to easy maintenance and cost reduction.

The supports 252 may be disposed between the split sheets 250a, 250b, 250c, 250d, 250e, 250f, and 250g. The supports 252 may protect or prevent the split sheets 250a, 250b, 250c, 250d, 250e, 250f, and 250g from sagging.

FIG. 9 is a plan view schematically illustrating a patterning slit sheet 350 according to another embodiment of the present invention. Referring to FIG. 9, the patterning slit sheet 350 may include a split sheet 350a, support sheets 350b and 350c, and supports 352.

The split sheet 350a may have a plurality of patterning slits 351, and the patterning slits 351 may be penetrated regions extending in a first direction (Y-axis direction) and may be arranged in a second direction (X-axis direction) perpendicular to the first direction. The support sheets 350b and 350c may be disposed at both sides of the split sheet 350a. The support sheets 350b and 350c may or may not have the patterning slits 351, in contrast with the split sheet 350a. Accordingly, an organic layer may only be formed on a region on the substrate 500 that corresponds to the split sheet 350a if the support sheet 350b and 350c do not have the patterning slits 351. The split sheet 350a and the support sheets 350b and 350c may be disposed in the second direction (X-axis direction).

Since the patterning slit sheet 350 includes the split sheet 350a and the support sheets 350b and 350c as described above, the tensile force of the patterning slit sheet 350 may be reduced, and thus deformation of the patterning slits 351 may be reduced. When some of the split sheet 350a and the support sheets 350b and 350c are damaged, only the damaged split sheet or support sheets may be replaced, leading to easy maintenance and cost reduction.

The supports 352 may be disposed between the split sheet 350a and the support sheet 350b and between the split sheet 350a and the support sheet 350c. The supports 352 may protect or prevent the split sheet 350a and the support sheets 350b and 350c from sagging.

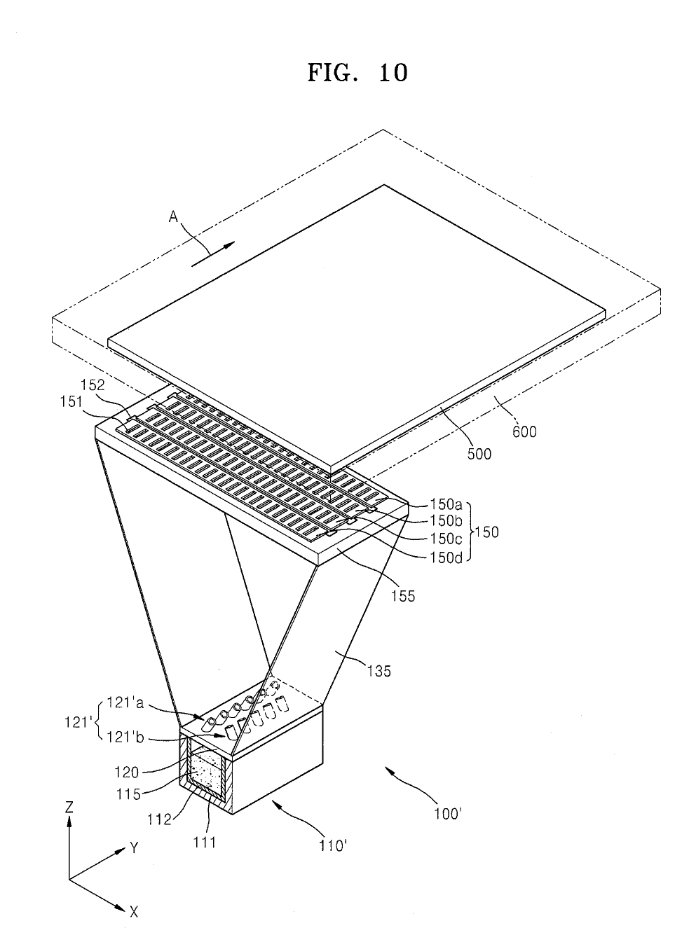

FIG. 10 is a schematic perspective view of an organic layer deposition apparatus 100′ according to another embodiment of the present invention. Referring to FIG. 10, the organic layer deposition apparatus 100′ according to the current embodiment of the present invention includes a deposition source 110′, the deposition source nozzle unit 120, and the patterning slit sheet 150. For example, the deposition source 110′ includes the crucible 112 that is filled with the deposition material 115, and the cooling block 111 that heats the crucible 112 to vaporize the deposition material 115, which is contained in the crucible 112, so as to move the vaporized deposition material 115 to the deposition source nozzle unit 120. The deposition source nozzle unit 120, which has a planar shape, is disposed at a side of the deposition source 110′. The deposition source nozzle unit 120 includes a plurality of deposition source nozzles 121′ arranged in the Y-axis direction. The patterning slit sheet 150 and the frame 155 are further disposed between the deposition source 110′ and the substrate 500. The patterning slit sheet 150 has a plurality of patterning slits 151 arranged in the X-axis direction. In addition, the deposition source 110′ and the deposition source nozzle unit 120 may be connected to the patterning slit sheet 150 by the connection member 135.

In the current embodiment, the plurality of deposition source nozzles 121′ formed on the deposition source nozzle unit 120 are tilted at a predetermined angle, unlike the organic layer deposition apparatus 100 described with reference to FIG. 4. In particular, the deposition source nozzles 121′ may include deposition source nozzles 121′a and 121′b arranged in respective rows. The deposition source nozzles 121′a and 121′b may be arranged in respective rows to alternate in a zigzag pattern. The deposition source nozzles 121′a and 121′b may be tilted (e.g., by a predetermined angle) with respect to a YZ plane.

In the current embodiment of the present invention, the deposition source nozzles 121′a and 121′b are arranged to tilt at a set or predetermined angle to each other. The deposition source nozzles 121′a in a first row and the deposition source nozzles 121′b in a second row may tilt to face each other. That is, the deposition source nozzles 121′a of the first row in a left part of the deposition source nozzle unit 120 are arranged to face a right side portion of the patterning slit sheet 150, and the deposition source nozzles 121b of the second row in a right part of the deposition source nozzle unit 120 are arranged to face a left side portion of the patterning slit sheet 150.

Due to the structure of the organic layer deposition apparatus 100′ according to the current embodiment, the deposition of the deposition material 115 may be adjusted to lessen a thickness variation between the center and the end portions of the substrate 500 and improve thickness uniformity of the deposition layer. Moreover, utilization efficiency of the deposition material 115 may also be improved.

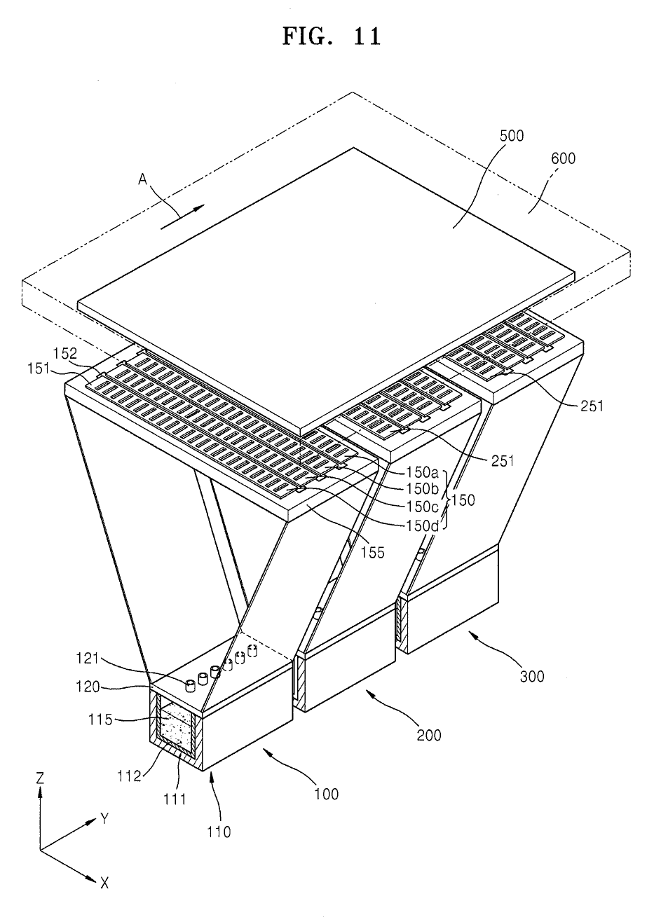

FIG. 11 is a schematic perspective view of an organic layer deposition apparatus according to another embodiment of the present invention. Referring to FIG. 11, the organic layer deposition apparatus according to the current embodiment of the present invention includes a plurality of organic layer deposition apparatuses, namely, first, second, and third organic layer deposition apparatuses 100, 200, and 300, each of which has the structure of the organic layer deposition apparatus 100 illustrated in FIGS. 4 through 6. In other words, the organic layer deposition apparatus according to the current embodiment of the present invention may include a multi-deposition source that concurrently (e.g., simultaneously) discharges deposition materials for forming an R emission layer, a G emission layer, and a B emission layer.

For example, the organic layer deposition apparatus according to the current embodiment of the present invention includes the first organic layer deposition apparatus 100, the second organic layer deposition apparatus 200, and the third organic layer deposition apparatus 300. Since each of the first organic layer deposition apparatus 100, the second organic layer deposition apparatus 200, and the third organic layer deposition apparatus 300 has the same structure as the organic layer deposition apparatus 100 described with reference to FIGS. 4 through 6, a detailed description thereof will not be provided here.

The deposition sources 110 of the first, second, and third organic layer deposition apparatuses 100, 200, and 300 may contain different deposition materials, respectively. The first organic layer deposition apparatus 100 may contain a deposition material used to form the R emission layer, the second organic layer deposition apparatus 200 may contain a deposition material used to form the G emission layer, and the third organic layer deposition apparatus 300 may contain a deposition material used to form the B emission layer.

In other words, in a conventional method of manufacturing an organic light-emitting display device, a separate chamber and a separate mask are used to form each color emission layer. However, when the organic layer deposition apparatus according to the current embodiment of the present invention is used, the R emission layer, the G emission layer, and the B emission layer may be formed concurrently (e.g., at the same time) with a single multi-deposition source. Thus, the time it takes to manufacture the organic light-emitting display device is sharply reduced. In addition, the organic light-emitting display device may be manufactured with a reduced number of chambers, so that equipment costs may also be reduced (e.g., markedly reduced).

Although not illustrated, a patterning slit sheet of the first organic layer deposition apparatus 100, a patterning slit sheet of the second organic layer deposition apparatus 200, and a patterning slit sheet of the third organic layer deposition apparatus 300 may be arranged to be offset by a constant or identical distance with respect to each other, in order for deposition regions corresponding to the patterning slit sheets to not overlap on the substrate 500. In other words, when the first organic layer deposition apparatus 100, the second organic layer deposition apparatus 200, and the third organic layer deposition apparatus 300 are used to deposit the R emission layer, the G emission layer, and the B emission layer, respectively, patterning slits 151 of the first organic layer deposition apparatus 100, patterning slits 251 of the second organic layer deposition apparatus 200, and patterning slits 351 of the third organic layer deposition apparatus 300 may be arranged to not be aligned or overlapped with respect to each other, in order to form the R emission layer, the G emission layer, and the B emission layer in different regions of the substrate 500.

In addition, the deposition materials used to form the R emission layer, the G emission layer, and the B emission layer may have different vaporization temperatures. Therefore, the temperatures of the deposition sources of the respective first, second, and third organic layer deposition assemblies 100, 200, and 300 may be set to be different.

Although FIG. 11 illustrates the three organic layer deposition apparatuses 100, 200, and 300, the present invention is not limited thereto. In other words, an organic layer deposition apparatus according to another embodiment of the present invention may include a plurality of organic layer deposition apparatuses, each of which contains a different deposition material. For example, an organic layer deposition apparatus according to another embodiment of the present invention may include five organic layer deposition apparatuses respectively containing materials for an R emission layer, a G emission layer, a B emission layer, an auxiliary layer (R′) of the R emission layer, and an auxiliary layer (G′) of the G emission layer.

As described above, a plurality of organic layers may be formed concurrently (e.g., at the same time) with a plurality of organic layer deposition apparatuses, and thus manufacturing yield and deposition efficiency may be improved. In addition, the overall manufacturing process may be simplified, and the manufacturing costs may be reduced.

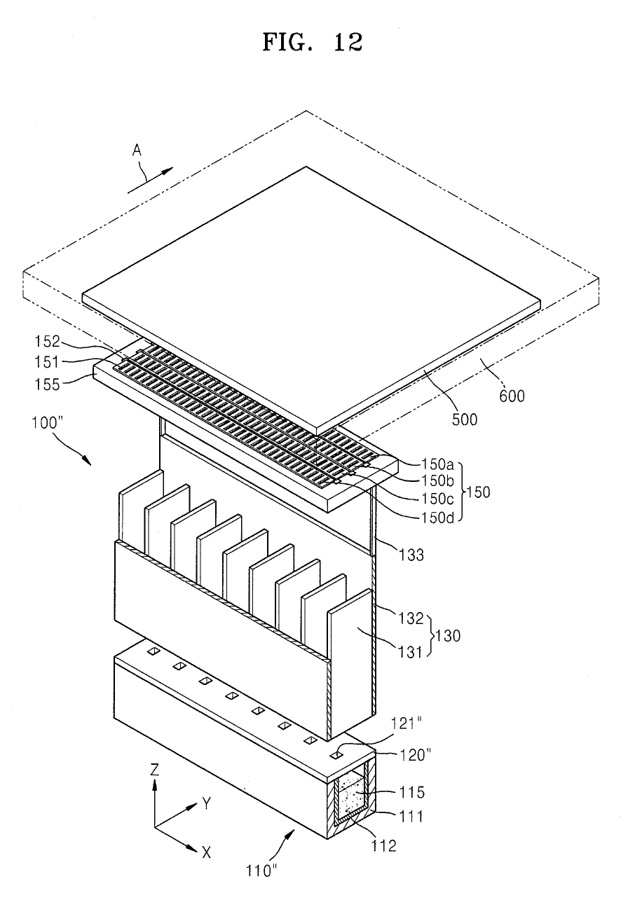

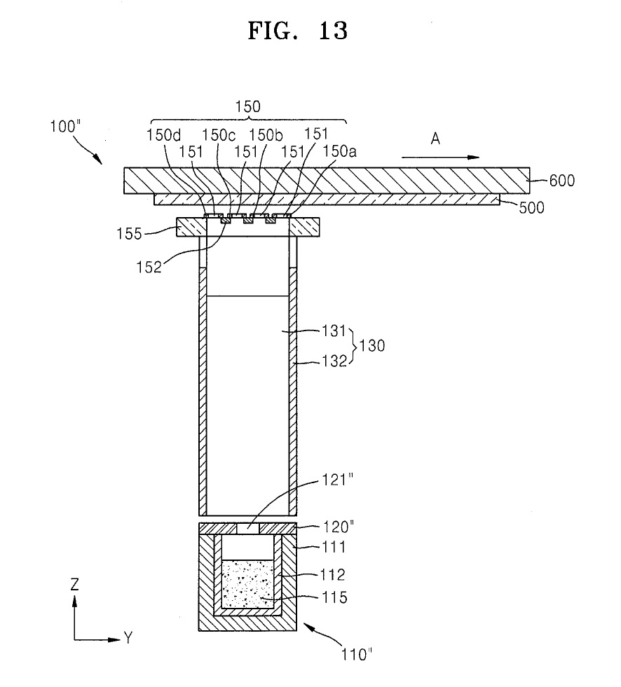

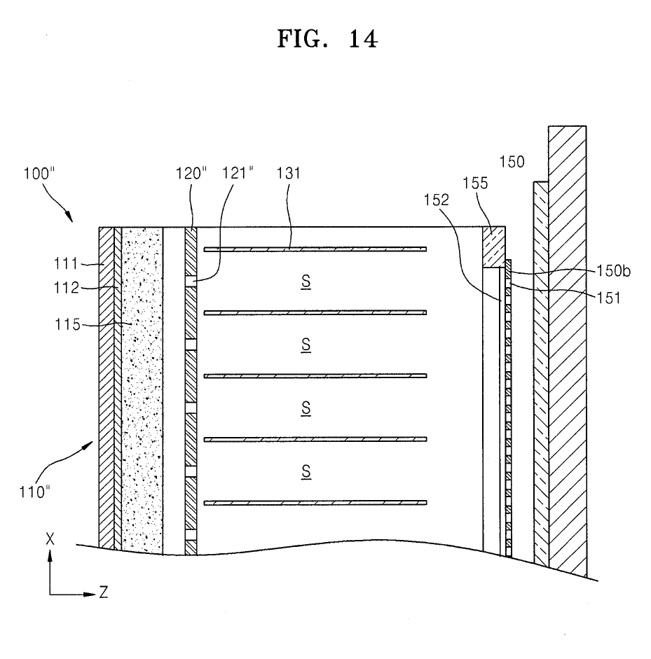

FIG. 12 is a schematic perspective cutaway view of an organic layer deposition apparatus 100″ according to another embodiment of the present invention, FIG. 13 is a schematic sectional view of the organic layer deposition apparatus 100″ illustrated in FIG. 12 in a plane parallel to the YZ plane, and FIG. 14 is a schematic sectional view of the organic layer deposition apparatus 100″ illustrated in FIG. 12 in a plane parallel to the XZ plane.

Referring to FIGS. 12 through 14, the organic layer deposition apparatus 100″ according to the current embodiment of the present invention includes a deposition source 110″, a deposition source nozzle unit 120″, a barrier plate assembly 130, and patterning slits 151.

Although a chamber is not illustrated in FIGS. 12 through 14 for convenience of explanation, all the components of the organic layer deposition apparatus 100″ may be disposed within a chamber that is maintained at an appropriate degree of vacuum. The chamber is maintained at an appropriate vacuum in order to allow a deposition material to move in a substantially straight line through the organic layer deposition apparatus 100″.

In the chamber 731 of FIG. 1 in which the organic layer deposition apparatus 100″ is disposed, the substrate 500, which constitutes a deposition target on which the deposition material 115 is to be deposited, is transferred by the electrostatic chuck 600. The substrate 500 may be a substrate for flat panel displays. A large substrate, such as a mother glass, for manufacturing a plurality of flat panel displays, may be used as the substrate 500. Other substrates may also be employed.

In an embodiment, the substrate 500 or the organic layer deposition apparatus 100″ may be moved relative to the other. For example, as illustrated in FIG. 12, the substrate 500 may be moved in a direction of an arrow A, relative to the organic layer deposition apparatus 100″.

Similar to the embodiment described above with reference to FIGS. 4 through 6, in the organic layer deposition apparatus 100″ according to the current embodiment of the present invention, the patterning slit sheet 150 may be smaller (e.g., significantly smaller) than an FMM used in a conventional deposition method. In other words, in the organic layer deposition apparatus 100″, deposition is continuously performed, i.e., in a scanning manner while the substrate 500 is moved in the Y-axis direction. Thus, a length of the patterning slit sheet 150 in the Y-axis direction may be less (e.g., significantly less) than a length of the substrate 500 provided a width of the patterning slit sheet 150 in the X-axis direction and a width of the substrate 500 in the X-axis direction are substantially equal to each other. However, even when the width of the patterning slit sheet 150 in the X-axis direction is less than the width of the substrate 500 in the X-axis direction, deposition may be performed on the entire substrate 500 in a scanning manner while the substrate 500 or the organic layer deposition apparatus 100″ is moved relative the other.

As described above, since the patterning slit sheet 150 may be formed to be significantly smaller than an FMM used in a conventional deposition method, it is relatively easy to manufacture the patterning slit sheet 150 used in the present invention. In other words, using the patterning slit sheet 150, which is smaller than an FMM used in a conventional deposition method, is more convenient in all processes, including etching and other subsequent processes, such as precise extension, welding, moving, and cleaning processes, compared to the conventional deposition method using the larger FMM. This is more advantageous for a relatively large display device.

The deposition source 110″ that contains and heats the deposition material 115 is disposed in an opposite side of the first chamber to a side in which the substrate 500 is disposed.

The deposition source 110″ includes a crucible 112 that is filled with the deposition material 115, and a cooling block 111 surrounding the crucible 112. The cooling block 111 reduces or prevents radiation of heat from the crucible 112 to the outside, e.g., into the first chamber 731 (see FIG. 1). The cooling block 111 may include a heater that heats the crucible 112.

The deposition source nozzle unit 120″ is disposed at a side of the deposition source 110″, and in particular, at the side of the deposition source 110″ facing the substrate 500. The deposition source nozzle unit 120″ includes a plurality of deposition source nozzles 121″ arranged at equal intervals in the X-axis direction. The deposition material 115 that is vaporized in the deposition source 110″ passes through the deposition source nozzles 121″ of the deposition source nozzle unit 120″ towards the substrate 500, which constitutes a target on which the deposition material 115 is to be deposited.

The barrier plate assembly 130 is disposed at a side of the deposition source nozzle unit 120″. The barrier plate assembly 130 includes a plurality of barrier plates 131, and a barrier plate frame 132 that covers sides of the barrier plates 131. The plurality of barrier plates 131 may be arranged parallel to each other at equal intervals in the X-axis direction. In addition, each of the barrier plates 131 may be arranged parallel to a YZ plane in FIG. 18, and may have a rectangular shape. The plurality of barrier plates 131 arranged as described above partition the space between the deposition source nozzle unit 120″ and the patterning slits 151 into a plurality of sub-deposition spaces S (see FIG. 14). In the organic layer deposition apparatus 100″ according to the current embodiment of the present invention, as illustrated in FIG. 13, the deposition space is divided by the barrier plates 131 into the sub-deposition spaces S that respectively correspond to the deposition source nozzles 121 through which the deposition material 115 is discharged.

The barrier plates 131 may be respectively disposed between adjacent deposition source nozzles 121″. In other words, each of the deposition source nozzles 121″ may be disposed between two adjacent barrier plates 131. The deposition source nozzles 121″ may be respectively located at the midpoint between two adjacent barrier plates 131. However, the present invention is not limited to this structure. For example, a plurality of deposition source nozzles 121″ may be disposed between two adjacent barrier plates 131. In this case, the deposition source nozzles 121″ may be also respectively located at the midpoint between two adjacent barrier plates 131.

As described above, since the barrier plates 131 partition the space between the deposition source nozzle unit 120″ and the patterning slit sheet 150 into the plurality of sub-deposition spaces S, the deposition material 115 discharged through each of the deposition source nozzles 121″ is not mixed with the deposition material 115 discharged through the other deposition source nozzles slits 121″, and passes through the patterning slits 151 so as to be deposited on the substrate 500. In other words, the barrier plates 131 guide the deposition material 115, which is discharged through the deposition source nozzles 121″, to move straight, i.e., to flow in the Z-axis direction.

As described above, the deposition material 115 is forced or guided to move straight by installing the barrier plates 131, so that a smaller shadow zone may be formed on the substrate 500 compared to a case where no barrier plates are installed. Thus, the organic layer deposition apparatus 100″ and the substrate 500 can be separated (or spaced) from each other by a set or predetermined distance. This will be described later in detail.

The barrier plate frame 132, which forms sides of the barrier plates 131, maintains the positions of the barrier plates 131, and guides the deposition material 115, which is discharged through the deposition source nozzles 121″, not to flow in the Y-axis direction. It should be noted that in FIG. 12, a portion of the barrier plate frame 132 on the left side has been cut away for illustrative purposes.

The deposition source nozzle unit 120″ and the barrier plate assembly 130 may be separated (or spaced) from each other (e.g., by a predetermined distance). This may reduce or prevent the heat radiated from the deposition source 110″ from being conducted to the barrier plate assembly 130. However, aspects of the present invention are not limited to this. For example, an appropriate heat insulator (not shown) may be further disposed between the deposition source nozzle unit 120″ and the barrier plate assembly 130. In this case, the deposition source nozzle unit 120″ and the barrier plate assembly 130 may be bound together with the heat insulator therebetween.

In addition, the barrier plate assembly 130 may be constructed to be detachable from the organic layer deposition apparatus 100″. In the organic layer deposition apparatus 100″ according to the current embodiment of the present invention, the deposition space is enclosed by using the barrier plate assembly 130, so that the deposition material 115 that remains undeposited may be mostly deposited within the barrier plate assembly 130. Thus, since the barrier plate assembly 130 is constructed to be detachable from the organic layer deposition apparatus 100″, when a large amount of the deposition material 115 lies in the barrier plate assembly 130 after a long deposition process, the barrier plate assembly 130 may be detached from the organic layer deposition apparatus 100″ and then placed in a separate deposition material recycling apparatus in order to recover the deposition material 115. Due to the structure of the organic layer deposition apparatus 100″ according to the present embodiment, a reuse rate of the deposition material 115 may be increased, so that the deposition efficiency may be improved and the manufacturing costs may be reduced.

The patterning slit sheet 150 and the frame 155 in which the patterning slit sheet 150 is bound are disposed between the deposition source 110″ and the substrate 500. The frame 155 may be formed to have a lattice shape, similar to a window frame. The patterning slit sheet 150 is bound inside the frame 155. The patterning slit sheet 150 includes a plurality of patterning slits 151 arranged in the X-axis direction. The patterning slits 151 extend in the Y-axis direction. The deposition material 115 that has been vaporized in the deposition source 110″ and passed through the deposition source nozzle 121″, passes through the patterning slits 151 towards the substrate 500.

The patterning slit sheet 150 may be formed of a metal thin film. The patterning slit sheet 150 is extended to be fixed to the frame 155. The patterning slits 151 may be formed by etching the patterning slit sheet 150 to have a stripe pattern.

In the organic layer deposition apparatus 100″ according to the current embodiment of the present invention, the total number of patterning slits 151 may be greater than the total number of deposition source nozzles 121″. In addition, there may be a greater number of patterning slits 151 than deposition source nozzles 121″ disposed between two adjacent barrier plates 131. The number of patterning slits 151 may be equal to the number of deposition patterns to be formed on the substrate 500.

In addition, the barrier plate assembly 130 and the patterning slit sheet 150 may be disposed to be separated (e.g., spaced) from each other (e.g., by a predetermined distance). Alternatively, the barrier plate assembly 130 and the patterning slit sheet 150 may be connected by the connection member 133. The temperature of the barrier plate assembly 130 may increase to 100° C. or higher due to the deposition source 110″ whose temperature is high. Thus, in order to prevent the heat of the barrier plate assembly 130 from being conducted to the patterning slit sheet 150, the barrier plate assembly 130 and the patterning slit sheet 150 are separated (or spaced) from each other (e.g., by a predetermined distance).

As described above, the organic layer deposition apparatus 100″ according to the current embodiment of the present invention performs deposition while being moved relative to the substrate 500. In order to move the organic layer deposition apparatus 100″ relative to the substrate 500, the patterning slit sheet 150 is separated (or spaced) from the substrate 500 (e.g., by a predetermined distance). In addition, in order to reduce or prevent the formation of a relatively large shadow zone on the substrate 500 when the patterning slit sheet 150 and the substrate 500 are separated from each other, the barrier plates 131 are arranged between the deposition source nozzle unit 120″ and the patterning slit sheet 150 to force the deposition material 115 to move in a straight direction. Thus, the size of the shadow zone that may be formed on the substrate 500 may be reduced (e.g., sharply reduced).

For example, in a conventional deposition method using an FMM, deposition is performed with the FMM in close contact with a substrate in order to prevent formation of a shadow zone on the substrate. However, when the FMM is used in close contact with the substrate, the contact may cause defects, such as scratches on patterns formed on the substrate. In addition, in the conventional deposition method, the size of the mask is the same as the size of the substrate since the mask cannot be moved relative to the substrate. Thus, the size of the mask is increased as display devices become larger. However, it is not easy to manufacture such a large mask.

In order to overcome this problem, in the organic layer deposition apparatus 100″ according to the current embodiment of the present invention, the patterning slit sheet 150 is disposed to be separated (or spaced) from the substrate 500 (e.g., by a predetermined distance). This may be facilitated by installing the barrier plates 131 to reduce the size of the shadow zone formed on the substrate 500.

As described above, when the patterning slit sheet 150 is manufactured to be smaller than the substrate 500, the patterning slit sheet 150 may be moved relative to the substrate 500 during deposition. Thus, it is no longer necessary to manufacture a large FMM as used in the conventional deposition method. In addition, since the substrate 500 and the patterning slit sheet 150 are separated from each other, defects caused due to contact therebetween may be prevented. In addition, since it is unnecessary to contact the substrate 500 with the patterning slit sheet 150 during a deposition process, the manufacturing speed may be improved.

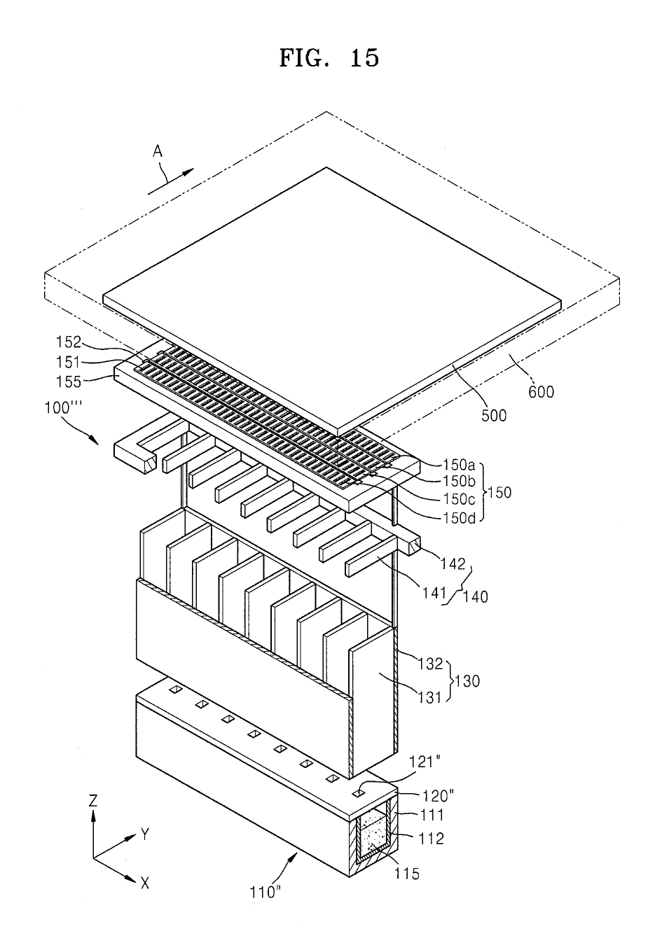

FIG. 15 is a schematic perspective cutaway view of an organic layer deposition apparatus 100′″ according to another embodiment of the present invention.

Referring to FIG. 15, the organic layer deposition apparatus 100′″ according to the current embodiment of the present invention includes a deposition source 110″, a deposition source nozzle unit 120″, a first barrier plate assembly 130, a second barrier plate assembly 140, and a patterning slit sheet 150.

Although a chamber is not illustrated in FIG. 15 for convenience of explanation, all the components of the organic layer deposition apparatus 500 may be disposed within a chamber that is maintained at an appropriate degree of vacuum. The chamber is maintained at an appropriate vacuum in order to allow a deposition material to move in a substantially straight line through the organic layer deposition apparatus 100′″.

The substrate 500, on which the deposition material 115 is to be deposited, is disposed in the chamber. The deposition source 110″ that contains and heats the deposition material 115 is disposed at an opposite side of the chamber to that in which the substrate 500 is disposed.

Structures of the deposition source 110″ and the patterning slit sheet 150 are the same as those in the embodiment described with reference to FIG. 12, and thus a detailed description thereof will not be provided here. The first barrier plate assembly 130 is also the same as the barrier plate assembly 130 of the embodiment described with reference to FIG. 12, and thus a detailed description thereof will not be provided here.

The second barrier plate assembly 140 is disposed at a side of the first barrier plate assembly 130. The second barrier plate assembly 140 includes a plurality of second barrier plates 141, and a second barrier plate frame 142 that covers sides of the second barrier plates 141. While a cutaway view of the second barrier plate assembly 140 is shown in FIG. 15, the second barrier plate frame 142 in practice may surround the second barrier plates 141.

The plurality of second barrier plates 141 may be arranged parallel to each other at equal intervals in the X-axis direction. In addition, each of the second barrier plates 141 may be formed to extend in the YZ plane in FIG. 15, i.e., perpendicular to the X-axis direction.

The plurality of first barrier plates 131 and second barrier plates 141 arranged as described above partition the space between the deposition source nozzle unit 120 and the patterning slit sheet 150. The deposition space is divided by the first barrier plates 131 and the second barrier plates 141 into sub-deposition spaces that respectively correspond to deposition source nozzles 121″ through which the deposition material 115 is discharged.

The second barrier plates 141 may be disposed to correspond respectively to the first barrier plates 131. The second barrier plates 141 may be respectively disposed to be parallel to and to be on the same plane as the first barrier plates 131. Each pair of the corresponding first and second barrier plates 131 and 141 may be located on the same plane. Although the first barrier plates 131 and the second barrier plates 141 are respectively illustrated as having the same thickness in the X-axis direction, aspects of the present invention are not limited thereto. For example, the second barrier plates 141, which are accurately aligned with the patterning slits 151, may be formed to be relatively thin, whereas the first barrier plates 131, which do not need to be precisely aligned with the patterning slits 151, may be formed to be relatively thick. This makes it easier to manufacture the organic layer deposition apparatus.

As illustrated in FIG. 1, a plurality of the above-described organic layer deposition apparatuses 100′″ may be successively disposed in the first chamber 731. In this case, the organic layer deposition apparatuses 100, 200, 300 and 400 may be used to deposit different deposition materials, respectively. For example, the organic layer deposition apparatuses 100, 200, 300 and 400 may have different patterning slit patterns, so that pixels of different colors, for example, red, green, and blue, may be concurrently (e.g., simultaneously) defined or formed through a film deposition process.

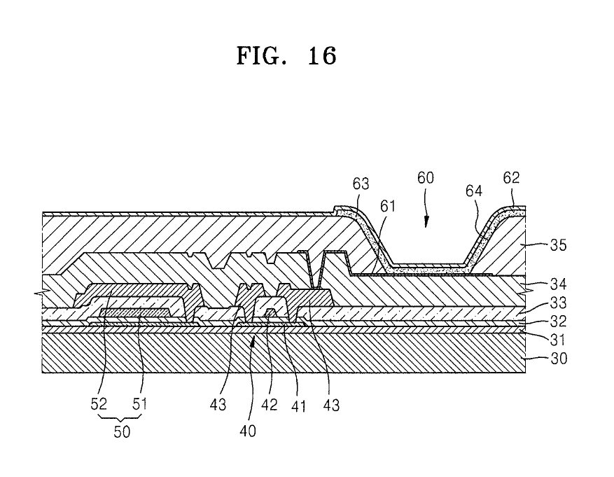

FIG. 16 is a cross-sectional view of an active matrix organic light-emitting display device fabricated by using an organic layer deposition apparatus, according to an embodiment of the present invention.

Referring to FIG. 16, the active matrix organic light-emitting display device according to the current embodiment, is formed on a substrate 30. The substrate 30 may be formed of a transparent material, for example, glass, plastic, or metal. An insulating layer 31, such as a buffer layer, is formed on an entire surface of the substrate 30.

A thin film transistor (TFT) 40, a capacitor 50, and an organic light-emitting diode (OLED) 60 are disposed on the insulating layer 31, as illustrated in FIG. 16. A semiconductor active layer 41 is formed on an upper surface of the insulating layer 31 (e.g., formed in a predetermined pattern). A gate insulating layer 32 is formed to cover the semiconductor active layer 41. The semiconductor active layer 41 may include a p-type or n-type semiconductor material.

A first capacitor electrode 51 of the capacitor 50 is formed on an upper surface of the gate insulating layer 32, and a gate electrode 42 of the TFT 40 is formed in a region on the upper surface of the gate insulating layer 32 corresponding to the semiconductor active layer 41. An interlayer insulating layer 33 is formed to cover the first capacitor electrode 51 and the gate electrode 42. The interlayer insulating layer 33 and the gate insulating layer 32 are etched by, for example, dry etching, to form a contact hole exposing parts of the semiconductor active layer 41.

Then, a second capacitor electrode 52 and a source/drain electrode 43 are formed on the interlayer insulating layer 33. The source/drain electrode 43 is formed on the interlayer insulating layer 33 to contact the semiconductor active layer 41 through the contact hole. A passivation layer 34 is formed to cover the second capacitor electrode 52 and the source/drain electrode 43, and is etched to expose a part of the drain electrode 43. An insulating layer may be further formed on the passivation layer 34 so as to planarize the passivation layer 34.

In addition, the OLED 60 displays image information (e.g., predetermined image information) by emitting red, green, or blue light as current flows. The OLED 60 includes a first electrode 61 disposed on the passivation layer 34. The first electrode 61 is electrically connected to the drain electrode 43 of the TFT 40.

A pixel defining layer 35 is formed to cover the first electrode 61. An opening 64 is formed in the pixel defining layer 35, and then an organic emission layer 63 is formed in a region defined by the opening 64. A second electrode 62 is formed on the organic emission layer 63.

The pixel defining layer 35, which defines individual pixels, is formed of an organic material. The pixel defining layer 35 also planarizes the surface of a region of the substrate 30 in which the first electrode 61 is formed, and in particular, the surface of the passivation layer 34.

The first electrode 61 and the second electrode 62 are insulated from each other, and respectively apply voltages of opposite polarities to the organic emission layer 63 to induce light emission.

The organic emission layer 63 may be formed of a low-molecular weight organic material or a high-molecular weight organic material. When a low-molecular weight organic material is used, the organic emission layer 63 may have a single or multi-layer structure including at least one selected from the group consisting of a hole injection layer (HIL), a hole transport layer (HTL), an emission layer (EML), an electron transport layer (ETL), and an electron injection layer (EIL). Examples of available organic materials may include copper phthalocyanine (CuPc), N,N′-di(naphthalene-1-yl)-N,N′-diphenyl-benzidine (NPB), tris-8-hydroxyquinoline aluminum (Alq3), and the like. Such a low-molecular weight organic material may be deposited using vacuum deposition by using a suitable one of the organic layer deposition apparatuses illustrated in the drawings. After the opening 64 is formed in the pixel defining layer 35, the substrate 30 is transferred to a chamber (not shown). Target organic materials are loaded into a first deposition source unit 11 and a second deposition source unit 12 for deposition. For example, when a host and a dopant are concurrently or simultaneously deposited, a host material and a dopant material may be loaded into the first deposition source unit 11 and the second deposition source unit 12, respectively.

After the organic emission layer 63 is formed, the second electrode 62 may be formed by the same deposition method as used to form the organic emission layer 63.

The first electrode 61 may function as an anode, and the second electrode 62 may function as a cathode. Alternatively, the first electrode 61 may function as a cathode, and the second electrode 62 may function as an anode. The first electrode 61 may be patterned to correspond to individual pixel regions, and the second electrode 62 may be formed to cover all the pixels.

The first electrode 61 may be formed as a transparent electrode or a reflective electrode. The transparent electrode may be formed of indium tin oxide (ITO), indium zinc oxide (IZO), zinc oxide (ZnO), and/or indium oxide (In₂O₃). The reflective electrode may be formed by forming a reflective layer from silver (Ag), magnesium (Mg), aluminum (Al), platinum (Pt), palladium (Pd), gold (Au), nickel (Ni), neodymium (Nd), iridium (Ir), chromium (Cr) or a compound thereof and forming a layer of ITO, IZO, ZnO, and/or In₂O₃ on the reflective layer. The first electrode 61 may be formed by forming a layer by, for example, sputtering, and then patterning the layer by, for example, photolithography.

The second electrode 62 may also be formed as a transparent electrode or a reflective electrode. When the second electrode 62 is formed as a transparent electrode, the second electrode 62 functions as a cathode. To this end, such a transparent electrode may be formed by depositing a metal having a low work function, such as lithium (Li), calcium (Ca), lithium fluoride/calcium (LiF/Ca), lithium fluoride/aluminum (LiF/Al), aluminum (Al), silver (Ag), magnesium (Mg), or a compound thereof on a surface of the intermediate layer 63 and forming an auxiliary electrode layer or a bus electrode line thereon from ITO, IZO, ZnO, In₂O₃, or the like. When the second electrode 62 is formed as a reflective electrode, the reflective electrode may be formed by depositing Li, Ca, LiF/Ca, LiF/AI, Al, Ag, Mg, or a compound thereof on the entire surface of the organic emission layer 63. The second electrode 62 may be formed by using the same deposition method as used to form the organic emission layer 63 described above.

The organic layer deposition apparatuses according to the embodiments of the present invention described above may be applied to form an organic layer or an inorganic layer of an organic TFT, and to form layers from various materials.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. An organic layer deposition apparatus for forming an organic layer on a substrate, the apparatus comprising:
a deposition source configured to discharge a deposition material;
a deposition source nozzle unit disposed at a side of the deposition source and comprising a plurality of deposition source nozzles arranged in a first direction; and
a patterning slit sheet disposed to face the deposition source nozzle unit and comprising a split sheet having a plurality of patterning slits arranged in a second direction perpendicular to the first direction and being smaller than the substrate in at least one of the first direction or the second direction,
wherein the organic layer deposition apparatus and the substrate are separated from each other, and the substrate or the organic layer deposition apparatus is configured to be moved relative to the other in the first direction to perform a deposition.

2. The organic layer deposition apparatus of claim 1, wherein the patterning slit sheet comprises a plurality of the split sheets, and a support is disposed between the split sheets.

3. The organic layer deposition apparatus of claim 2, wherein the split sheets are arranged in the first direction.

4. The organic layer deposition apparatus of claim 3, wherein a length of a side of each of the split sheets parallel to the second direction is greater than a length of a side of each of the split sheets parallel to the first direction.

5. The organic layer deposition apparatus of claim 2, wherein the split sheets are arranged in the second direction.

6. The organic layer deposition apparatus of claim 5, wherein a length of a side of each of the split sheets parallel to the second direction is smaller than a length of a side of each of the split sheets parallel to the first direction.

7. The organic layer deposition apparatus of claim 1, wherein
the patterning slit sheet further comprises support sheets, and
the support sheets are disposed at opposite sides of the split sheet, respectively.

8. The organic layer deposition apparatus of claim 7, wherein the patterning slit sheet further comprises supports that are disposed between the support sheets and the split sheet to support the support sheets and the split sheet.

9. The organic layer deposition apparatus of claim 1, wherein the deposition source, the deposition source nozzle unit, and the patterning slit sheet are integrally formed as one body.

10. The organic layer deposition apparatus of claim 1, wherein the deposition source and the deposition source nozzle unit, and the patterning slit sheet are integrally connected as one body via a connection member for guiding movement of the deposition material.

11. The organic layer deposition apparatus of claim 10, wherein the connection member seals a space between the deposition source nozzle unit disposed at the side of the deposition source, and the patterning slit sheet.

12. The organic layer deposition apparatus of claim 1, wherein the plurality of deposition source nozzles are tilted at an angle.

13. The organic layer deposition apparatus of claim 12, wherein the plurality of deposition source nozzles include deposition source nozzles arranged in two rows formed in the first direction, and the deposition source nozzles in the two rows are tilted to face each other.

14. The organic layer deposition apparatus of claim 12, wherein
the plurality of deposition source nozzles comprises deposition source nozzles arranged in two rows formed in the first direction, and
the deposition source nozzles of one of the two rows located at a first side of the patterning slit sheet are arranged to face a second side of the patterning slit sheet, and the deposition source nozzles of the other one of the two rows located at the second side of the patterning slit sheet are arranged to face the first side of the patterning slit sheet.

15. An organic layer deposition apparatus for forming an organic layer on a substrate, the apparatus comprising:
a deposition source configured to discharge a deposition material;
a deposition source nozzle unit disposed at a side of the deposition source and comprising a plurality of deposition source nozzles arranged in a first direction;
a patterning slit sheet disposed to face the deposition source nozzle unit, having a plurality of patterning slits arranged in the first direction, and being smaller than the substrate in at least the first direction or a second direction perpendicular to the first direction; and
a barrier plate assembly comprising a plurality of barrier plates disposed between the deposition source nozzle unit and the patterning slit sheet in the first direction, and partitioning a space between the deposition source nozzle unit and the patterning slit sheet into a plurality of sub-deposition spaces,
wherein the organic layer deposition apparatus and the substrate are separated from each other, and
the organic layer deposition apparatus or the substrate is configured to be moved relative to the other.

16. The organic layer deposition apparatus of claim 15, wherein the plurality of barrier plates extend in a third direction perpendicular to the first direction and the second direction and/or extend in the second direction.

17. The organic layer deposition apparatus of claim 15, wherein the barrier plate assembly comprises a first barrier plate assembly comprising a plurality of first barrier plates, and a second barrier plate assembly comprising a plurality of second barrier plates.

18. The organic layer deposition apparatus of claim 17, wherein each of the first barrier plates and each of the second barrier plates extend in a third direction perpendicular to the first direction and the second direction and/or extend in the second direction.

19. The organic layer deposition apparatus of claim 18, wherein the first barrier plates are arranged to respectively correspond to the second barrier plates.

20. The organic layer deposition apparatus of claim 15, wherein the deposition source and the barrier plate assembly are separated from each other.

21. The organic layer deposition apparatus of claim 15, wherein the barrier plate assembly and the patterning slit sheet are separated from each other.

22. The organic layer deposition apparatus of claim 15, wherein the patterning slit sheet comprises a plurality of split sheets, and a support is disposed between the plurality of split sheets.

23. The organic layer deposition apparatus of claim 22, wherein the plurality of split sheets are arranged in the first direction.

24. The organic layer deposition apparatus of claim 23, wherein a length of a side of each of the plurality of split sheets parallel to the second direction is greater than a length of a side of each of the plurality of split sheets parallel to the first direction.

25. The organic layer deposition apparatus of claim 22, wherein the plurality of split sheets are arranged in the second direction.

26. The organic layer deposition apparatus of claim 25, wherein a length of a side of each of the plurality of split sheets parallel to the second direction is smaller than a length of a side of each of the plurality of split sheets parallel to the first direction.

27. The organic layer deposition apparatus of claim 15, wherein
the patterning slit sheet comprises a split sheet having the plurality of patterning slits and a plurality of support sheets, and
the support sheets are disposed at opposite sides of the split sheet, respectively.

28. The organic layer deposition apparatus of claim 27, wherein the patterning slit sheet further comprises supports disposed between the support sheets and the split sheet to support the support sheets and the split sheet.

29. A method of manufacturing an organic light-emitting display device, the method comprising:
separating an organic layer deposition apparatus from a substrate on which deposition is to occur, by a distance, wherein the organic layer deposition apparatus comprises: a deposition source that discharges a deposition material; a deposition source nozzle unit disposed at a side of the deposition source and comprising a plurality of deposition source nozzles arranged in a first direction; and a patterning slit sheet disposed to face the deposition source nozzle unit, comprising a split sheet having a plurality of patterning slits, and being smaller than the substrate in at least the first direction or a second direction perpendicular to the first direction; and
depositing the deposition material discharged from the organic layer deposition apparatus onto the substrate while the organic layer deposition apparatus or the substrate is moved relative to the other.

30. The method of claim 29, wherein
the patterning slit sheet further comprises support sheets, and
the support sheets are disposed at opposite sides of the split sheet, respectively.

31. The method of claim 30, wherein the patterning slit sheet further comprises supports disposed between the support sheets and the split sheet to support the support sheets and the split sheet.

32. The method of claim 29, wherein
the deposition source nozzle unit comprises the plurality of deposition source nozzles arranged in the first direction, and
the patterning slit sheet has the plurality of patterning slits arranged in the second direction.

33. The method of claim 29, wherein
the deposition source nozzle unit comprises the plurality of deposition source nozzles arranged in the first direction,
the patterning slit sheet has the plurality of patterning slits arranged in the first direction, and
the organic layer deposition apparatus further comprises a barrier plate assembly comprising a plurality of barrier plates that are disposed between the deposition source nozzle unit and the patterning slit sheet in the first direction, and partition a space between the deposition source nozzle unit and the patterning slit sheet into a plurality of sub-deposition spaces.

34. An organic light-emitting display device manufactured using the organic layer deposition apparatus of claim 1.
